(19) United States
(12) Patent Application Publication
(10) Pub. No.: US 2013/0108965 A1
(43) Pub. Date: May 2, 2013

(54) RADIATION-SENSITIVE COMPOSITION

(71) Applicant: JSR Corporatioon, Tokyo (JP)

(72) Inventors: Masayuki MIYAKE, Tokyo (JP); Tooru KIMURA, Tokyo (JP); Atsushi NAKAMURA, Tokyo (JP); Yuji YADA, Tokyo (JP)

(73) Assignee: JSR CORPORATION, Tokyo (TW)

(21) Appl. No.: 13/723,299

(22) Filed: Dec. 21, 2012

Related U.S. Application Data
(63) Continuation of application No. PCT/JP2011/064305, filed on Jun. 22, 2011.

(30) Foreign Application Priority Data
Jun. 23, 2010 (JP) 2010-142606

(51) Int. Cl. G03F 7/004

(52) U.S. Cl. CPC G03F 7/004
USPC 430/286.1

(57) ABSTRACT

A radiation-sensitive composition includes a polymer component, a radiation-sensitive acid generator and a solvent component. The polymer component includes a first polymer that includes an acidic group, a group in which an acidic group is protected by an acid-dissociable group, or a both thereof. The solvent component includes a first solvent which is a solvent shown by a general formula (C1-a), a solvent shown by a general formula (C1-b), a solvent shown by a general formula (C1-c), or a mixture thereof.

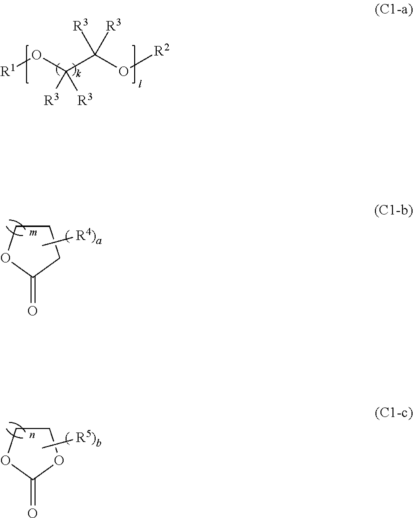

### CROSS-REFERENCE TO RELATED APPLICATIONS

The present application is a continuation application of International Application No. PCT/JP2011/064305, filed Jun. 22, 2011, which claims priority to Japanese Patent Application No. 2010-142606, filed Jun. 23, 2010. The contents of these applications are incorporated herein by reference in their entirety.

### BACKGROUND OF THE INVENTION

1. Field of the Invention

The invention relates to a radiation-sensitive composition.

2. Discussion of the Background

In the field of microfabrication such as production of integrated circuit devices, a photolithographic process that achieves a reduction in processing size has been desired in order to achieve a higher degree of integration. In order to deal with such a demand, photolithography that utilizes radiation having a shorter wavelength has been studied. Photolithography that utilizes deep ultraviolet rays (e.g., KrF excimer laser light (wavelength: 248 nm) or ArF excimer laser light (wavelength: 193 nm)) has been put to practical use, and widely used to produce integrated circuit devices.

A “chemically-amplified resist” that includes a radiation-sensitive acid generator that generates an acid upon exposure to radiation (hereinafter may be referred to as “exposure”), and exhibits improved sensitivity due to the catalytic effect of the acid generated by the radiation-sensitive acid generator, has been used as a resist suitable for photolithography that utilizes deep ultraviolet rays.

A resist composition that includes a resin of which the acidic group is protected by a t-butyl group or a t-butoxycarbonyl group, and a radiation-sensitive acid generator has been proposed as a material for forming a chemically-amplified resist suitable for KrF excimer laser light (see Japanese Patent Application Publication No. 59-45439, for example). A composition that includes a resin of which the acidic group is protected by a silyl group, and a radiation-sensitive acid generator have also been proposed (see Japanese Patent Application Publication No. 60-52845, for example). Moreover, there have been proposed a number of proposal about chemically-amplified resist such as a composition that includes an acetal group-containing resin, and a radiation-sensitive acid generator (see Japanese Patent Application Publication No. 2-25850, for example), and the like.

In recent years, the structure of integrated circuit devices has become complex, and there are more and more lithographic processes which include forming resist patterns on a substrate which has unevenness of polysilicon when producing a three-dimensional transistor or the like (e.g., Fin-FET). In such a process, since a plurality of materials is present on a single substrate, and the reflectivity of radiation during exposure that is reflected by the surface of the substrate varies due to the difference in material of the substrate, it may be difficult to form a uniform resist pattern.

An underlayer antireflective film may be formed between the substrate and the resist in order to reduce reflection of radiation by the surface of the substrate. However, in a lithography process where it is impossible to form the underlayer antireflective film (i.e., when the resist pattern is used as an ion implantation mask), the reflectivity of the surface of the substrate is high, and thus standing waves may occur due to interference between radiation that enters the resist and radiation that is reflected by the surface of the substrate. This may result in such problems that wave-like irregularity may be formed on the sidewall of the resist pattern, or the pattern shape may be deteriorated.

A technique that reduces the deterioration in pattern shapes due to standing waves by adding a dye to the resist has been proposed in order to solve the above problems (see Patent Japanese Patent Application Publication No. 7-319155 and Japanese Patent Application Publication No. 11-265061, for example).

### SUMMARY OF THE INVENTION

According to one aspect of the present invention, a radiation-sensitive composition includes a polymer component, a radiation-sensitive acid generator and a solvent component. The polymer component includes a first polymer that includes an acidic group, a group in which an acidic group is protected by an acid-dissociable group, or a both thereof. The solvent component includes a first solvent which is a solvent shown by a general formula (C1-a), a solvent shown by a general formula (C1-b), a solvent shown by a general formula (C1-c), or a mixture thereof.

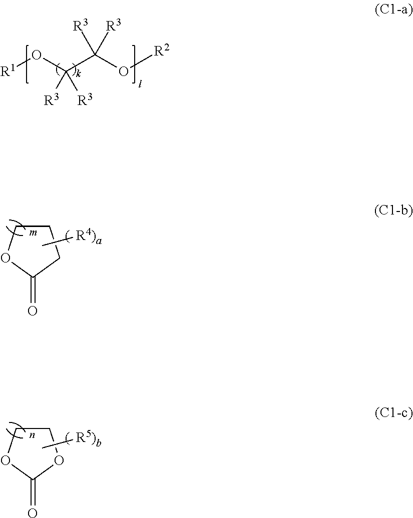

In the general formula (C1-a), each of R¹ and R² independently represents a hydrogen atom, a linear or branched alkyl group having 1 to 10 carbon atoms, an aryl group having 6 to 15 carbon atoms, an aralkyl group having 7 to 15 carbon atoms, a halogen atom, a group shown by a general formula (c1), or a group shown by a general formula (c2). Each R³ independently represents a hydrogen atom, a linear or branched alkyl group having 1 to 5 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2). k is an integer from 1 to 10. l is an integer from 2 to 5. In the general formula (C1-b), R⁴ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2). m is an integer from 2 to 4. a is an integer from 0 to 12, wherein in case a plurality of R⁴s are present, each of the plurality of R⁴s is identical or different to each other. In the general formula (C1-c), R⁵ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2). n is an integer from 2 to 4. b is an integer from 0 to 10, wherein in case a plurality of R⁵s are present, each of the plurality of R⁵s is identical or different to each other.

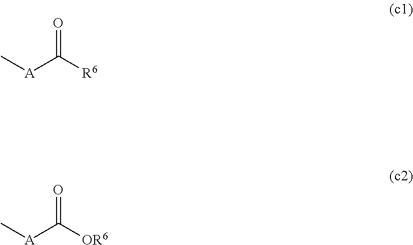

In the general formulas (c1) and (c2), each A independently represents a single bond or a divalent hydrocarbon group having 1 to 5 carbon atoms. Each R⁶ independently represents a hydrogen atom or a monovalent hydrocarbon group having 1 to 5 carbon atoms.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating the effects of standing waves in a line area of a resist pattern.

### DESCRIPTION OF THE EMBODIMENTS

One aspect of embodiments of the present invention provides the following radiation-sensitive composition.

[1] A radiation-sensitive composition including (A) a polymer component that includes a polymer that includes at least one of an acidic group and an acidic group that is protected by an acid-dissociable group, (B) a radiation-sensitive acid generator, and (C) a solvent component that includes a solvent (C1), the solvent (C1) being at least one solvent selected from a group consisting of a solvent shown by a general formula (C1-a), a solvent shown by a general formula (C1-b), and a solvent shown by a general formula (C1-c),

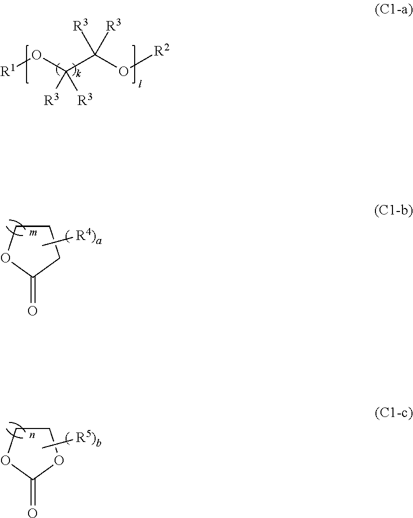

wherein, in the general formula (C1-a), R¹ and R² independently represent a hydrogen atom, a linear or branched alkyl group having 1 to 10 carbon atoms, an aryl group having 6 to 15 carbon atoms, an aralkyl group having 7 to 15 carbon atoms, a halogen atom, a group shown by a general formula (c1), or a group shown by a general formula (c2); R³ independently represent a hydrogen atom, a linear or branched alkyl group having 1 to 5 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2); k is an integer from 1 to 10; l is an integer from 2 to 5; in the general formula (C1-b), R⁴ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2); m is an integer from 2 to 4; a is an integer from 0 to 12, provided that in case a plurality of R⁴s is present, the plurality of R⁴s may be independent to each other; in the general formula (C1-c), R⁵ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2); n is an integer from 2 to 4; and b is an integer from 0 to 10, provided that in case a plurality of R⁵s is present, the plurality of R⁵s may be independent to each other,

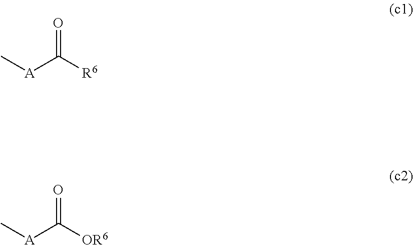

wherein, in the general formulas (c1) and (c2), A independently represents a single bond or a divalent hydrocarbon group having 1 to 5 carbon atoms; and R⁶ independently represents a hydrogen atom or a monovalent hydrocarbon group having 1 to 5 carbon atoms.
[2] The radiation-sensitive composition according to [1], wherein a content of the solvent (C1) in the solvent component (C) is 0.01 to 30 mass % of the total solvent component (C).
[3] The radiation-sensitive composition according to [1] or [2], wherein the polymer is a polymer (A1) which includes a repeating unit (a1) shown by a general formula (a1),

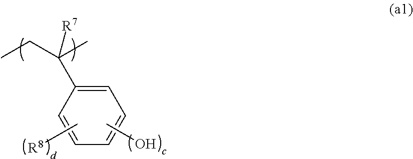

wherein, in the general formula (a1), R⁷ represents a hydrogen atom, a methyl group, or a trifluoromethyl group; R⁸ represents a linear or branched alkyl group having 1 to 12 carbon atoms or a linear or branched alkoxy group having 1 to 12 carbon atoms; c is an integer from 1 to 3; and d is an integer from 0 to 4, provided that in case a plurality of R⁸s is present, the plurality of R⁸s may be independent to each other.
[4] The radiation-sensitive composition according to [3], wherein the repeating unit (a1) is a repeating unit derived from hydroxystyrene (hereinafter, may be referred to as “hydroxystyrene unit”).
[5] The radiation-sensitive composition according to any one of [1] to [4], wherein the polymer component (A) includes a polymer (A2) that includes an acidic group that is protected by an acid-dissociable group.
[6] The radiation-sensitive composition according to any one of [3] to [5], wherein a content of the polymer (A1) in the polymer component (A) is 50 to 100 mass %, the radiation-sensitive composition further comprising (D) a crosslinking agent, and being capable of forming a negative type resist pattern.

Since the radiation-sensitive composition of the embodiment of the present invention includes the solvent (C1) that is at least one solvent selected from the group consisting of the solvent (C1-a), the solvent (C1-b), and the solvent (C1-c), the radiation-sensitive composition exhibits the advantage that it can form a resist pattern on a substrate that has high radiation reflectivity, or a substrate that has partially different radiation reflectivity at the surface of the substrate due to the presence of a plurality of materials so that the resist exhibits excellent sensitivity and resolution, and can prevent a situation in which wave-like irregularity is formed on the sidewall of the resist pattern, or the pattern shape is deteriorated due to standing waves that occur due to interference between radiation that enters the resist and radiation that is reflected by the surface of the substrate.

The embodiments of the invention are now described below in detail. It is to be noted that the invention is not limited to the following embodiments. Various modifications and improvements may be made of the following embodiments without departing from the scope of the invention based on the knowledge of a person having ordinary skill in the art.

### [1] Radiation-Sensitive Composition

A radiation-sensitive composition according to the embodiment of the invention includes (A) a polymer component, (B) a radiation-sensitive acid generator, and (C) a solvent component. The details of each component are described below.

### [1-1] Polymer Component (A)

The polymer component (A) includes at least one of a polymer (A1) that includes an acidic group and a polymer (A2) that includes an acidic group that is protected by an acid-dissociable group. The radiation-sensitive composition according to the embodiment of the invention can form both a positive type resist pattern and a negative type resist pattern due to the polymer component (A).

When the radiation-sensitive composition according to the embodiment of the invention includes the polymer component (A) that includes the polymer (A1) that includes an acidic group, the radiation-sensitive acid generator (B), and (D) a crosslinking agent that causes a crosslinking reaction due to an acid generated by the radiation-sensitive acid generator (B), the radiation-sensitive composition functions as a resist material that can form a negative type resist pattern in which the exposed area is crosslinked, and which remains after development.

When the radiation-sensitive composition according to the embodiment of the invention includes the polymer component (A) that includes the polymer (A2) that includes an acidic group that is protected by an acid-dissociable group, and the radiation-sensitive acid generator (B), the radiation-sensitive composition functions as a resist material that can form a positive type resist pattern in which the acid-dissociable group dissociates in the exposed area, so that the acidic group is deprotected, and removed by a developer.

### [1-1-1] Polymer (A1)

It is preferable that the polymer component (A) include the polymer (A1) that includes a phenolic hydroxyl group-containing repeating unit (a1) shown by the general formula (a1).

Examples of the linear or branched alkyl group having 1 to 12 carbon atoms represented by R⁸ in the general formula (a1) include a methyl group, an ethyl group, an n-propyl group, an i-propyl group, an n-butyl group, an s-butyl group, an i-butyl group, a t-butyl group, an n-pentyl group, and the like. Among these, a methyl group, an ethyl group, an n-propyl group, and an i-propyl group are preferable since the rectangularity of the pattern shape can be improved.

Examples of the linear or branched alkoxy group having 1 to 12 carbon atoms represented by R⁸ in the general formula (a1) include a group obtained by adding an oxygen atom to the bonding site of the linear or branched alkyl group having 1 to 12 carbon atoms, and the like. Among these, a group obtained by adding an oxygen atom to the bonding site of a methyl group, an ethyl group, an n-propyl group, or an i-propyl group is preferable since the rectangularity of the pattern shape can be improved.

c in the general formula (a1) is an integer from 1 to 3, and preferably 1. d in the general formula (a1) is an integer from 0 to 4, preferably an integer from 0 to 2, and more preferably 0. Specifically, it is particularly preferable that the repeating unit (a1) be a repeating unit (hydroxystyrene unit) derived from hydroxystyrene. Note that the sum (c+d) of c and d is 5 or less because of the structure of the repeating unit (a1).

Examples of a monomer that produces the hydroxystyrene unit included in the polymer (A1) include o-hydroxystyrene, m-hydroxystyrene, p-hydroxystyrene, and the like. Among these, p-hydroxystyrene is a particularly preferable from the viewpoint of the structural stability and the acidity of the phenolic hydroxyl group. Specifically, it is preferable that the polymer (A1) include a repeating unit derived from p-hydroxystyrene.

The content of the repeating unit (a1) in the polymer (A1) is preferably 50 to 90 mol %, more preferably 60 to 90 mol %, and particularly preferably 65 to 85 mol %, based on the total repeating units included in the polymer (A1). When the content of the repeating unit (a1) is within the above range (i.e., the polymer (A1) includes a specific amount of hydroxyl groups), the radiation-sensitive composition that includes the polymer (A1) in an amount equal to or more than a specific amount exhibits improved solubility in an alkaline developer, and may suitably be used as a radiation-sensitive composition for forming a negative type resist pattern.

The polymer (A1) may include an arbitrary repeating unit other than the repeating unit (a1). It is preferable that the polymer (A1) include at least one of a repeating unit derived from styrene (hereinafter may be referred to as “styrene unit”) and a repeating unit derived from α-methylstyrene (hereinafter may be referred to as “α-methylstyrene unit”) due to excellent polymerization reactivity with the repeating unit (a1).

It is preferable that the polymer (A1) be at least one of a hydroxystyrene/styrene copolymer having a hydroxystyrene content of 60 to 90 mol % and a hydroxystyrene/α-methylstyrene copolymer having a hydroxystyrene content of 65 to 90 mol % (hereinafter may be referred to as “specific hydroxystyrene copolymer”).

When the polymer (A1) is the specific hydroxystyrene copolymer, the content of the hydroxystyrene unit in the specific hydroxystyrene copolymer is preferably 60 to 90 mol %, and more preferably 65 to 85 mol %, based on the total repeating units included in the specific hydroxystyrene copolymer. When the content of the hydroxystyrene unit is within the above range, a pattern having excellent rectangularity can be obtained while increasing the exposure margin. If the content of the hydroxystyrene unit is less than 60 mol %, the dissolution rate of the polymer (A1) in an alkaline developer may decrease, so that the developability and the resolution of the resulting resist may be deteriorated. If the content of the hydroxystyrene unit exceeds 90 mol %, the resulting resist may not be sufficiently hardened, so that the exposed area may be dissolved in a developer, and the pattern shape may be deteriorated (i.e., a pattern having a rectangular shape may not be obtained).

The repeating unit (a1) provides the polymer (A1) with solubility in an alkaline developer. Specifically, the radiation-sensitive composition according to the embodiment of the invention can form a negative type resist pattern when the radiation-sensitive composition includes the polymer (A1) that includes the repeating unit (a1), the radiation-sensitive acid generator (B), and the crosslinking agent (D).

The weight average molecular weight (Mw) of the polymer (A1) is preferably 2000 to 8000, and more preferably 3000 to 7000. The dispersity of the polymer (A1) that is defined by the ratio (Mw/Mn) of the weight average molecular weight (Mw) to the number average molecular weight (Mn) is preferably 1.8 or less, and more preferably 1.6 or less. If the weight average molecular weight (Mw) of the polymer (A1) is less than 2000, the film-forming capability of the resulting radiation-sensitive composition, the sensitivity of the resulting resist, or the like may be deteriorated due to a low degree of polymerization of the polymer (A1). If the weight average molecular weight (Mw) of the polymer (A1) exceeds 8000, the sensitivity of the resulting resist may be deteriorated due to a high degree of polymerization of the polymer (A1). If the dispersity of the polymer (A1) exceeds 1.8, the size of the polymer in the resulting resist film may vary, so that a sufficient contrast may not be obtained. As a result, the resolution of the resulting resist may be deteriorated.

Note that the polymer component (A) may include only one type of the polymer (A1), or may include two or more types of the polymer (A1).

When the polymer component (A) is used for a negative type radiation-sensitive composition, the content of the polymer (A1) in the polymer component (A) is preferably 50 to 100 mol %, more preferably 70 to 100 mol %, and particularly preferably 80 to 100 mol %. When the content of the polymer (A1) is within the above range, a pattern having excellent rectangularity can be obtained while increasing the exposure margin.

The polymer (A1) may be produced by an arbitrary known method. For example, the specific hydroxystyrene copolymer may be produced by (i) subjecting a monomer obtained by protecting the hydroxyl group of hydroxystyrene with a protecting group (e.g., buthoxycarbonyloxystyrene, butoxystyrene, acetoxystyrene, or tetrahydropyranyloxystyrene) to addition polymerization with at least one of styrene and α-methylstyrene, and removing the protecting group via hydrolysis in the presence of an acidic catalyst or a basic catalyst, or (ii) subjecting hydroxystyrene to addition polymerization with at least one of styrene and α-methylstyrene. It is preferable to use the method (i) since the specific hydroxystyrene copolymer can be efficiently produced.

The monomers may be polymerized by radical polymerization, anionic polymerization, cationic polymerization, thermal polymerization, or the like. It is preferable to employ anionic polymerization or cationic polymerization since the dispersity of the resulting copolymer can be reduced. Examples of the acidic catalyst used for the method (i) include inorganic acids such as hydrochloric acid and sulfuric acid. Examples of the basic catalyst used for the method (i) include organic bases such as trialkylamines, and inorganic bases such as sodium hydroxide.

### [1-1-2] Polymer (A2)

The polymer component (A) may include the polymer (A2) that includes an acidic group that is protected by an acid-dissociable group (e.g., phenolic hydroxyl group or carboxyl group). The dissolution rate of the resulting resist in a developer increases when the radiation-sensitive composition according to the embodiment of the invention includes the polymer (A2). Specifically, the dissolution rate of the resulting resist in a developer can be controlled by adjusting the content of the polymer (A2) in the radiation-sensitive composition according to the embodiment of the invention, so that a pattern having excellent rectangularity can be obtained.

It is preferable that the polymer (A2) include at least one of a repeating unit shown by the following general formula (a2) (hereinafter may be referred to as “repeating unit (a2)”) and a repeating unit shown by the following general formula (a3) (hereinafter may be referred to as “repeating unit (a3)”).

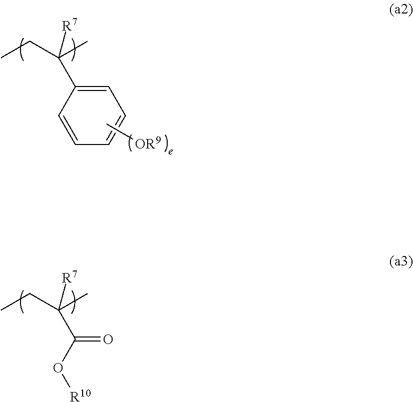

wherein, in the general formulas (a2) and (a3), R⁷ represents a hydrogen atom, a methyl group, or a trifluoromethyl group; in the general formula (a2), R⁹ represents a monovalent acid-dissociable group; e is an integer from 1 to 3, provided that in case a plurality of R⁹s is present, the plurality of R⁹s may be independent to each other; and in the general formula (a3), R¹⁰ represents a monovalent acid-dissociable group.

Examples of a preferable polymerizable monomer that produces the repeating unit (a2) include 4-t-butoxystyrene, 4-(2-ethyl-2-propoxy)styrene, 4-(1-ethoxyethoxy)styrene, t-butoxycarbonylstyrene, t-butoxycarbonylmethylenestyrene, and the like. Note that the polymer (A2) may include only one type of the repeating unit (a2), or may include two or more types of the repeating unit (a2).

Examples of a preferable polymerizable monomer that produces the repeating unit (a3) include t-butyl(meth)acrylate, 2-methyl-2-adamantyl(meth)acrylate, 2-ethyl-2-adamantyl(meth)acrylate, 1-methylcyclopentyl(meth)acrylate, 1-ethylcyclopentyl(meth)acrylate, 2,5-dimethyl-2,5-hexanediol di(meth)acrylate, and the like. Note that the polymer (A2) may include only one type of the repeating unit (a3), or may include two or more types of the repeating unit (a3).

The term “(meth)acrylic acid” used herein refers to acrylic acid or methacrylic acid, and the term “(meth)acrylate” used herein refers to an acrylate or a methacrylate.

The polymer (A2) may further include the repeating unit (a1).

A 4-hydroxystyrene/4-t-butoxystyrene copolymer, a 4-hydroxystyrene/4-t-butoxystyrene/1-methylcyclopentyl acrylate copolymer, a 4-hydroxystyrene/4-t-butoxystyrene/1-ethylcyclopentyl acrylate copolymer, a 4-hydroxystyrene/4-t-butoxystyrene/styrene copolymer, a 4-hydroxystyrene/t-butyl acrylate/styrene copolymer, a 4-hydroxystyrene/1-methylcyclopentyl acrylate/styrene copolymer, a 4-hydroxystyrene/1-ethylcyclopentyl acrylate/styrene copolymer, and a 4-hydroxystyrene/4-t-butoxystyrene/2,5-dimethyl-2,5-hexanediol diacrylate copolymer are particularly preferable as the polymer (A2).

The polystyrene-reduced weight average molecular weight (Mw) of the polymer (A2) determined by gel permeation chromatography (GPC) is preferably 1000 to 150,000, more preferably 3000 to 100,000, and particularly preferably 3000 to 50,000. The ratio (dispersity) (Mw/Mn) of the Mw to the polystyrene-reduced number average molecular weight (Mn) of the polymer (A2) determined by GPC is preferably 1 to 10, more preferably 1 to 5, and particularly preferably 1 to 2.5.

Note that the polymer component (A) may include only one type of the polymer (A2), or may include two or more types of the polymer (A2).

When the polymer component (A) is used for a negative type radiation-sensitive composition, the content of the polymer (A2) in the polymer component (A) is preferably 0 to 30 mol %, more preferably 0 to 20 mol %, and particularly preferably 0 to 10 mol %. When the content of the polymer (A2) is 30 mol % or less, a pattern having excellent rectangularity can be obtained while increasing the exposure margin. If the content of the polymer (A2) exceeds 30 mol %, the difference in solubility between the exposed area and the unexposed area (i.e., the contrast) may decrease, so that the shape of the resulting pattern may be deteriorated.

When the polymer component (A) is used for a positive type radiation-sensitive composition, the content of the polymer (A2) in the polymer component (A) is preferably 50 to 100 mol %, more preferably 50 to 90 mol %, and particularly preferably 50 to 80 mol %. When the content of the polymer (A2) is within the above range, the sensitivity can be adjusted, and high resolution can be obtained.

### [1-2] Radiation-Sensitive Acid Generator (B)

It is preferable to use an onium salt compound such as an iodonium salt compound shown by the following general formula (B3) or a sulfonium salt compound shown by the following general formula (B4) as the radiation-sensitive acid generator (B).

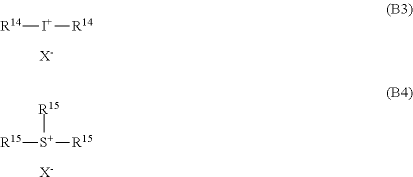

wherein, in the general formulas (B3) and (B4), X⁻ represents a sulfonate anion shown by R—SO₃⁻, R represents a fluorine atom, a hydroxyl group, an alkoxy group, an aliphatic hydrocarbon group that may be substituted with a carboxyl group, an aryl group, or a group derived therefrom; in the general formula (B3), R¹⁴ independently represent a substituted or unsubstituted linear or branched alkyl group having 1 to 10 carbon atoms or a substituted or unsubstituted aryl group having 6 to 18 carbon atoms, provided that R¹⁴ may bond to each other to form a cyclic structure together with the iodine atom that is bonded to R¹⁴; and, in the general formula (B4), R¹⁵ independently represent a substituted or unsubstituted linear or branched alkyl group having 1 to 10 carbon atoms or a substituted or unsubstituted aryl group having 6 to 18 carbon atoms, provided that two of R¹⁵ may bond to each other to form a cyclic structure together with the sulfur atom that is bonded to R¹⁵, and the remainder of R¹⁵ may represent a substituted or unsubstituted linear or branched alkyl group having 1 to 10 carbon atoms or a substituted or unsubstituted aryl group having 6 to 18 carbon atoms.

Examples of the substituted or unsubstituted linear or branched alkyl group having 1 to 10 carbon atoms represented by R¹⁴ or R¹⁵ in the general formula (B3) or (B4) include a methyl group, an ethyl group, an n-propyl group, an i-propyl group, an n-butyl group, an s-butyl group, an i-butyl group, a t-butyl group, an n-pentyl group, and the like.

Examples of the substituted or unsubstituted linear or branched aryl group having 6 to 18 carbon atoms represented by R¹⁴ or R¹⁵ in the general formula (B3) or (B4) include a phenyl group, a 4-methylphenyl group, a 2,4,6-trimethylphenyl group, a 4-hydroxyphenyl group, a 4-fluorophenyl group, a 2,4-fluorophenyl group, and the like.

Examples of the sulfonium ion represented by X⁻ in the general formulas (B3) and (B4) include trifluoromethanesulfonate, nonafluoro-n-butanesulfonate, benzenesulfonate, p-toluenesulfonate, 10-camphorsulfonate, 2-trifluoromethylbenzenesulfonate, 4-trifluoromethylbenzenesulfonate, 2,4-difluorobenzenesulfonate, perfluorobenzenesulfonate, 2-(bicyclo[2.2.1]heptan-2-yl)-1,1-difluoroethanesulfonate, 2-(bicyclo[2.2.1]heptan-2-yl)ethanesulfonate, and the like. These sulfonium ions may be used either alone or in combination.

The radiation-sensitive acid generator (B) (hereinafter may be referred to as “acid generator (B)”) generates an acid upon exposure to radiation. A nonionic radiation-sensitive acid generator (e.g., a sulfonyloxyimide compound shown by the following general formula (B1) or a sulfonyldiazomethane compound shown by the following general formula (B2)) may also be used as the acid generator (B).

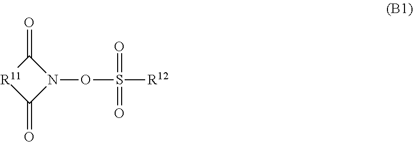

wherein, in the general formula (B1), R¹¹ represents a divalent hydrocarbon group, and R¹² represents a substituted or unsubstituted alkyl group, a substituted or unsubstituted aryl group, or a halogen atom.

Examples of the divalent hydrocarbon group represented by R¹¹ in the general formula (B1) include alkylene groups, arylene groups, alkoxylene groups, cycloalkylene groups, cycloalkylene groups that include a cyclic skeleton that includes an unsaturated bond, and the like.

Examples of the alkyl group represented by R¹² in the general formula (B1) include alkyl groups that may be substituted with a halogen atom, alkyl groups that may include a camphor skeleton, and cycloalkyl groups that may include an ester bond. Examples of the aryl group represented by R¹² include aryl groups that may be substituted with a halogen atom or an alkyl group.

Examples of the sulfonyloxyimide compound shown by the general formula (B1) include N-(trifluoromethanesulfonyloxy)bicyclo[2.2.1]hept-5-ene-2,3-dicarboxyimide, N-(10-camphorsulfonyloxy)succinimide, N-(4-toluenesulfonyloxy)succinimide, N-(nonafluoro-n-butanesulfonyloxy)bicyclo[2.2.1]hept-5-ene-2,3-dicarboxyimide, N-(benzenesulfonyloxy)bicyclo[2.2.1]hept-5-ene-2,3-dicarboxyimide, N-{(5-methyl-5-carboxymethylbicyclo[2.2.1]heptan-2-yl)sulfonyloxy}succinimide, and the like. These sulfonyloxyimide compounds may be used either alone or in combination.

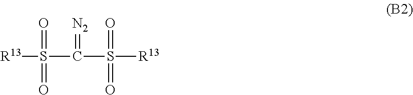

wherein, in the general formula (B2), R¹³ independently represent a monovalent organic group.

Examples of the monovalent organic group represented by R¹³ in the general formula (B2) include alkyl groups, aryl groups, halogen-substituted alkyl groups, halogen-substituted aryl groups, and the like.

Examples of the sulfonyldiazomethane compound shown by the general formula (B2) include bis(trifluoromethanesulfonyl)diazomethane, bis(cyclohexanesulfonyl)diazomethane, bis(phenylsulfonyl)diazomethane, bis(4-toluenesulfonyl)diazomethane, bis(2,4-dimethylbenzenesulfonyl)diazomethane, bis(4-t-butylbenzenesulfonyl)diazomethane, bis(4-chlorobenzenesulfonyl)diazomethane, methylsulfonyl.4-toluenesulfonyldiazomethane, cyclohexanesulfonyl.4-toluenesulfonyldiazomethane, cyclohexanelsulfonyl.1,1-dimethylethanesulfonyldiazomethane, bis(1,1-dimethylethanesulfonyl)diazomethane, bis(1-methylethanesulfonyl)diazomethane, bis(3,3-dimethyl-1,5-dioxaspiro[5.5]dodecane-8-sulfonyl)diazomethane, and bis(1,4-dioxaspiro[4.5]decane-7-sulfonyl)diazomethane, and the like. These sulfonyldiazomethane compounds may be used either alone or in combination.

The acid generator (B) is preferably used in an amount of 0.1 to 20 parts by mass, and more preferably 0.5 to 15 parts by mass, based on 100 parts by mass of the polymer component (A). If the amount of the acid generator (B) is too small, the sensitivity and the developability of the resulting resist may be deteriorated. If the amount of the acid generator (B) is too large, the resulting resist may exhibit poor transparency to radiation, and the shape, the heat resistance, and the like of the resulting resist pattern may be deteriorated.

An additional acid generator may be used as the acid generator (B) in addition to the onium salt compound, the sulfonyloxyimide compound, and the sulfonyldiazomethane compound. The content of the additional acid generator in the acid generator (B) is preferably 30 mass % or less, and more preferably 10 mass % or less. If the content of the additional acid generator is too high, the sensitivity and the developability of the resulting resist may be deteriorated.

### [1-3] Solvent Component (C)

The radiation-sensitive composition according to the embodiment of the invention is prepared by dissolving the polymer component (A), the acid generator (B), and an optional additional component (described later) in the solvent component (C).

The solvent component (C) is preferably used in such an amount that the total solid content in the radiation-sensitive composition according to the embodiment of the invention is 0.1 to 50 mass %, and more preferably 1 to 40 mass %.

### [1-3-1] Solvent (C1)

The solvent component (C) includes a solvent (C1). The solvent (C1) is at least one solvent selected from the group consisting of a solvent (C1-a) shown by the general formula (C1-a), a solvent (C1-b) shown by the general formula (C1-b), and a solvent (C1-c) shown by the general formula (C1-c). Note that the solvent (C1-a), the solvent (C1-b), and the solvent (C1-c) have a boiling point of 165° C. or more.

Since the radiation-sensitive composition according to the embodiment of the invention includes the solvent (C1) that is at least one solvent selected from the group consisting of the solvent (C1-a), the solvent (C1-b), and the solvent (C1-c) that have a boiling point of 165° C. or more, the solvent (C1) remains in the resist film without volatilizing when the radiation-sensitive composition is applied to a substrate, and pre-baked (PB). It is conjectured that diffusion of an acid generated by the radiation-sensitive acid generator (B) upon exposure to radiation is thus promoted, and the above phenomenon prevents a situation in which irregularity is formed on the sidewall of the resist pattern due to the effects of standing waves caused by radiation that enters the resist film, and reflected radiation that occurs when radiation that has entered the resist film is reflected at the lower end of the resist film.

The solvent (C1) has a boiling point of 165° C. or more, preferably 165 to 250° C., more preferably 165 to 230° C., and particularly preferably 170 to 220° C. When the boiling point of the solvent (C1) is within the above range, the solvent (C1) more reliably remains in the resist film even if the radiation-sensitive composition is pre-baked (PB), so that the effects of standing waves can be reduced. If the boiling point of the solvent (C1) is less than 165° C., the solvent (C1) may volatilize when the radiation-sensitive composition is pre-baked (PB), so that the effects of standing waves may not be reduced (i.e., irregularity may be formed on the sidewall of the resist pattern). Note that the boiling point of the solvent (C1) refers to a value measured at 101.3 kPa.

Examples of the linear or branched alkyl group having 1 to 10 carbon atoms represented by R¹ and R² in the general formula (C1-a), R⁴ in the general formula (C1-b), and R⁵ in the general formula (C1-c) include a methyl group, an ethyl group, an n-propyl group, an i-propyl group, an n-butyl group, an s-butyl group, an i-butyl group, a t-butyl group, an n-pentyl group, an n-hexyl group, an n-heptyl group, and the like. Among these, linear or branched alkyl groups having 1 to 5 carbon atoms are preferable.

Examples of the aryl group having 6 to 15 carbon atoms represented by R¹, R² and R³ in the general formula (C1-a), R⁴ in the general formula (C1-b), and R⁵ in the general formula (C1-c) include a phenyl group, a tolyl group, and the like. Among these, aryl groups having 6 to 10 carbon atoms are preferable, and aryl groups having 6 to 8 carbon atoms are particularly preferable.

Examples of the aralkyl group having 7 to 15 carbon atoms represented by R¹, R², and R³ in the general formula (C1-a), R⁴ in the general formula (C1-b), and R⁵ in the general formula (C1-c) include a benzyl group and the like. Among these, aralkyl groups having 7 to 12 carbon atoms are preferable, and aralkyl groups having 7 to 10 carbon atoms are particularly preferable.

Examples of the halogen atom represented by R¹, R², and R³ in the general formula (C1-a), R⁴ in the general formula (C1-b), and R⁵ in the general formula (C1-c) include a chlorine atom (Cl), a fluorine atom (F), a bromine atom (Br), an iodine atom (I), and the like.

Examples of the linear or branched alkyl group having 1 to 5 carbon atoms represented by R³ in the general formula (C1-a) include a methyl group, an ethyl group, an n-propyl group, an i-propyl group, an n-butyl group, an s-butyl group, an i-butyl group, a t-butyl group, an n-pentyl group, and the like. Among these, a methyl group, an ethyl group, an n-propyl group, an i-propyl group, an n-butyl group, an s-butyl group, an i-butyl group, and a t-butyl group are preferable.

Examples of the alkoxy group having 1 to 5 carbon atoms represented by R³ in the general formula (C1-a) include a methoxy group, an ethoxy group, an n-propoxy group, an i-propoxy group, an n-butoxy group, an s-butoxy group, an i-butoxy group, a t-butoxy group, an n-pentyloxy group, and the like. Among these, a methoxy group, an ethoxy group, an n-propoxy group, an i-propoxy group, an n-butoxy group, an s-butoxy group, an i-butoxy group, and a t-butoxy group are preferable.

Examples of the divalent hydrocarbon group having 1 to 5 carbon atoms represented by A in the general formula (c1) or (c2) include a methylene group, an ethylene group, an n-propylene group, an i-propylene group, an n-butylene group, an i-butylene group, an n-pentene group, and the like. A preferably represents a single bond or a divalent hydrocarbon group having 1 to 4 carbon atoms, and particularly preferably a single bond or a divalent hydrocarbon group having 1 to 3 carbon atoms.

Examples of the monovalent hydrocarbon group having 1 to 5 carbon atoms represented by R⁶ in the general formula (c1) or (c2) include a methyl group, an ethyl group, an n-propyl group, an i-propyl group, an n-butyl group, an i-butyl group, an n-pentyl group, and the like. R⁶ preferably represents a hydrogen atom or a monovalent hydrocarbon group having 1 to 4 carbon atoms, and particularly preferably a hydrogen atom or a monovalent hydrocarbon group having 1 to 3 carbon atoms.

l in the general formula (C1-a) is an integer from 2 to 5, preferably an integer from 2 to 4, and particularly preferably 2 or 3.

Examples of the solvent (C1-a) include diethylene glycol monomethyl ether acetate, diethylene glycol monoethyl ether acetate, diethylene glycol monobutyl ether acetate, diethylene glycol diethyl ether, diethylene glycol dibutyl ether, dipropylene glycol monomethyl ether acetate, dipropylene glycol monoethyl ether acetate, diethylene glycol monoethyl ether, diethylene glycol monobutyl ether, and the like. Among these, diethylene glycol diethyl ether, diethylene glycol monoethyl ether acetate, and dipropylene glycol monomethyl ether acetate are particularly preferable.

m in the general formula (C1-b) is an integer from 2 to 4, preferably 2 or 3, and particularly preferably 2.

a in the general formula (C1-b) is an integer from 0 to 12. Note that the maximum value of a is determined depending on the structure of the solvent (C1-b) and the value of m, and is indicated by a=2m+4. For example, the maximum value of a is 4 when m is 0, and is 12 when m is 4.

Examples of the solvent (C1-b) include δ-valerolactone, δ-hexanolactone, δ-octanolactone, α-methyl-δ-valerolactone, α,α-dimethyl-δ-valerolactone, α-acetyl-δ-valerolactone, α-chloro-δ-valerolactone, α-bromo-δ-valerolactone, β-chloro-δ-valerolactone, β-bromo-δ-valerolactone, ε-caprolactone, and the like. Among these, δ-valerolactone is particularly preferable.

n in the general formula (C1-c) is an integer from 2 to 4, preferably 2 or 3, and particularly preferably 2.

b in the general formula (C1-c) is an integer from 0 to 10. Note that the maximum value of b is determined depending on the structure of the solvent (C1-c) and the value of n, and is indicated by b=2n+2. For example, the maximum value of b is 2 when n is 0, and is 10 when n is 4.

Examples of the solvent (C1-c) include 4-ethyl-1,3-dioxan-2-one, 1,3-dioxan-2-one, 3-methyl-1,3-dioxan-2-one, 4-methyl-1,3-dioxan-2-one, 3-ethyl-1,3-dioxan-2-one, 4-ethyl-1,3-dioxan-2-one, 3-propyl-1,3-dioxan-2-one, 4-propyl-1,3-dioxan2-one, 3-bromo-1,3-dioxan-2-one, 4-bromo-1,3-dioxan-2-one, 3-chloro-1,3-dioxan-2-one, 4-chloro-1,3-dioxan-2-one, and the like. Among these, 4-ethyl-1,3-dioxan-2-one is particularly preferable.

The content of the solvent (C1) in the solvent component (C) is preferably 0.01 to 50 mass %, more preferably 0.01 to 20 mass %, and particularly preferably 0.01 to 15 mass %. If the content of the solvent (C1) is within the above range, the acid generated by the acid generator (B) can be efficiently diffused, so that a resist pattern having an excellent pattern shape (i.e., rectangular shape) can be formed. If the content of the solvent (C1) is less than 0.01 mass %, the solvent (C1) achieves only a small acid diffusion effect, so that irregularity may be formed on the sidewall of the resist pattern (i.e., a resist pattern having an inferior shape may be obtained). If the content of the solvent (C1) exceeds 50 mass %, the acid diffusion effect due to the solvent (C1) increases to a large extent, so that the acid may be diffused into the unexposed area (i.e., a resist having poor dimensional accuracy may be obtained).

### [1-3-2] Solvent (C2)

The solvent component (C) may include an additional solvent (hereinafter may be referred to as “solvent (C2)”) in addition to the solvent (C1).

Examples of the solvent (C2) include ethers, esters, ether esters, ketone esters, ketones, amides, amide esters, lactams, lactones (excluding the compounds shown by the general formula (C1-b)), (halogenated) hydrocarbons, and the like. Specific examples of the solvent (C2) include ethylene glycol monoalkyl ethers, diethylene glycol dialkyl ethers (excluding the compounds shown by the general formula (C1-a)), propylene glycol monoalkyl ethers, propylene glycol dialkyl ethers, ethylene glycol monoalkyl ether acetates, diethylene glycol monoalkyl ether acetates (excluding the compounds shown by the general formula (C1-b)), propylene glycol monoalkyl ether acetates, dipropylene glycol monoalkyl ether acetates (excluding the compounds shown by the general formula (C1-a)), acetates, hydroxyacetates, alkoxyacetates, acetoacetates, propionates, lactates, alkoxypropionate, butyrates, pyruvates, cyclic (non-cyclic) ketones, N,N-dialkylformamides, N,N-dialkylacetamides, N-alkylpyrrolidones, γ-lactones, (halogenated) aliphatic hydrocarbons, (halogenated) aromatic hydrocarbons, and the like.

Specific examples of the solvent (C2) include ethylene glycol monomethyl ether acetate, ethylene glycol monoethyl ether acetate, ethylene glycol mono-n-propyl ether acetate, ethylene glycol mono-n-butyl ether acetate, propylene glycol monomethyl ether, propylene glycol monoethyl ether, propylene glycol mono-n-propyl ether, propylene glycol mono-n-butyl ether, propylene glycol dimethyl ether, propylene glycol diethyl ether, propylene glycol di-n-propyl ether, propylene glycol di-n-butyl ether, propylene glycol monomethyl ether acetate, propylene glycol monoethyl ether acetate, propylene glycol mono-n-propyl ether acetate, propylene glycol mono-n-butyl ether acetate,

methyl lactate, ethyl lactate, n-propyl lactate, i-propyl lactate, n-amyl formate, i-amyl formate, ethyl acetate, n-propyl acetate, i-propyl acetate, n-butyl acetate, i-butyl acetate, n-amyl acetate, i-amyl acetate, i-propyl propionate, n-butyl propionate, i-butyl propionate, ethyl hydroxyacetate, ethyl 2-hydroxy-2-methylpropionate, methyl 2-hydroxy-3-methylbutyrate, ethyl methoxyacetate, ethyl ethoxyacetate, methyl 3-methoxypropionate, ethyl 3-methoxypropionate, methyl 3-ethoxypropionate, ethyl 3-ethoxypropionate, 3-methoxybutyl acetate, 3-methyl-3-methoxybutyl acetate, 3-methyl-3-methoxybutyl propionate, 3-methyl-3-methoxybutyl butyrate, methyl acetoacetoate, ethyl acetoacetate, methyl pyruvate, ethyl pyruvate, toluene, xylene, methyl ethyl ketone, 2-pentanone, 2-hexanone, 2-heptanone, 3-heptanone, 4-heptanone, cyclohexanone, N-methylformamide, N,N-dimethylformamide, N-methylacetamide, N,N-dimethylacetamide, N-methylpyrrolidone, γ-butyrolactone, propylene carbonate, and the like.

Among these, propylene glycol monoalkyl ether acetates, lactates, 3-alkoxypropionates, cyclic (non-cyclic) ketones, and the like are preferable. These solvents (C2) may be used either alone or in combination.

### [1-4] Crosslinking Agent (D)

When the radiation-sensitive composition according to the embodiment of the invention is used to form a negative type resist pattern, it is preferable that the radiation-sensitive composition further include (D) a crosslinking agent. Specifically, a negative type resist pattern may be formed when the radiation-sensitive composition according to the embodiment of the invention includes the crosslinking agent (D), and the content of the polymer (A1) in the polymer component (A) is 50 to 100 mass %. When the radiation-sensitive composition according to the embodiment of the invention includes the crosslinking agent (D), a crosslinking reaction due to the crosslinking agent (D) is promoted by the catalytic effect of the acid generated by the acid generator (B) upon exposure to radiation, so that different molecules and individual molecules of the polymer (A) are crosslinked to form a crosslinked polymer that exhibits low solubility in an alkaline developer. Therefore, a negative type resist pattern can be formed by development.

The crosslinking agent (D) is not particularly limited as long as the crosslinking agent (D) can crosslink the polymer (A) so that a crosslinked polymer that is insoluble in an alkaline developer is obtained. Examples of the crosslinking agent (D) include a compound that includes a group shown by the following general formula (D1), a compound that includes a group shown by the following general formula (D2), a compound that includes a group shown by the following general formula (D3), a compound that includes a group shown by the following general formula (D4), a compound that includes a group shown by the following general formula (D5), and the like.

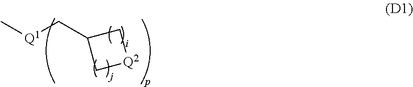

wherein, in the general formula (D1), Q¹ represents a single bond, an oxygen atom, a sulfur atom, a carbonyloxy group, an amino group, or a nitrogen atom; Q² represents an oxygen atom or a sulfur atom; p is 1 or 2; i is an integer from 0 to 3; and j is an integer from 1 to 3, provided that i+j=1 to 4 is satisfied.

Examples of the group shown by the general formula (D1) include a glycidyl ether group, a glycidyl ester group, a glycidylamino group, and the like.

Q¹ in the general formula (D1) represents a single bond, an oxygen atom, a sulfur atom, a carbonyloxy group, or an amino group when p is 1, and represents a nitrogen atom (trivalent) when p is 2.

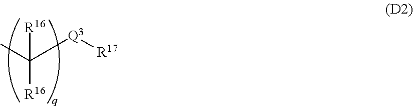

wherein, in the general formula (D2). Q³ represents an oxygen atom, a carbonyl group, or a carbonyloxy group; R¹⁶ independently represent a hydrogen atom or an alkyl group having 1 to 4 carbon atoms; R¹⁷ represents an alkyl group having 1 to 5 carbon atoms, an aryl group having 6 to 12 carbon atoms, or an aralkyl group having 7 to 14 carbon atoms, and q is an integer equal to or larger than 1.

Examples of the group shown by the general formula (D2) include a methoxymethyl group, an ethoxymethyl group, a benzyloxymethyl group, an acetoxymethyl group, a benzoyloxymethyl group, a formyl group, an acetyl group, and the like.

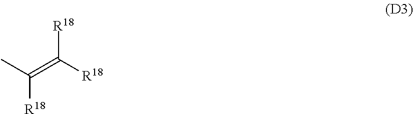

wherein, in the general formula (D3), R¹⁸ independently represent a hydrogen atom or an alkyl group having 1 to 4 carbon atoms.

Examples of the group shown by the general formula (D3) include a vinyl group, an isopropenyl group, and the like.

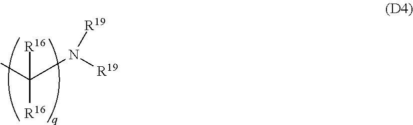

wherein, in the general formula (D4), R¹⁶ independently represent a hydrogen atom or an alkyl group having 1 to 4 carbon atoms; R¹⁹ independently represent an alkyl group having 1 to 5 carbon atoms or an alkylol group having 1 to 5 carbon atoms; and q is an integer equal to or larger than 1.

Note that R¹⁶ and q in the general formula (D4) are the same as R¹⁶ and q in the general formula (D2).

Examples of the group shown by the general formula (D4) include a dimethylaminomethyl group, a diethylaminomethyl group, a dimethylolaminomethyl group, a diethylolaminomethyl group, and the like.

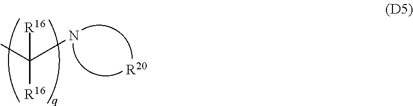

wherein, in the general formula (D5), R¹⁶ independently represent a hydrogen atom or an alkyl group having 1 to 4 carbon atoms; R²⁰ forms a divalent 3 to 8-membered heterocyclic group that further includes an oxygen atom, a sulfur atom, or a nitrogen atom together with the nitrogen atom that is bonded to R²⁰; and q is an integer equal to or larger than 1.

Note that R¹⁶ and q in the general formula (D5) are the same as R¹⁶ and q in the general formulas (D2) and (D4).

Examples of the group shown by the general formula (D5) include a morpholylmethyl group and the like.

Examples of the compounds that include any of the above crosslinkable functional groups include bisphenol A epoxy compounds, bisphenol F epoxy compounds, bisphenol S epoxy compounds, novolac resin epoxy compounds, resol resin epoxy compounds, poly(hydroxystyrene) epoxy compounds, methylol group-containing melamine compounds, methylol group-containing benzoguanamine compounds, methylol group-containing urea compounds, methylol group-containing phenol compounds, alkoxyalkyl group-containing melamine compounds, alkoxyalkyl group-containing benzoguanamine compounds, alkoxyalkyl group-containing urea compounds, alkoxyalkyl group-containing phenol compounds, carboxymethyl group-containing melamine resins, carboxymethyl group-containing benzoguanamine resins, carboxymethyl group-containing urea resins, carboxymethyl group-containing phenol resins, carboxymethyl group-containing melamine compounds, carboxymethyl group-containing benzoguanamine compounds, carboxymethyl group-containing urea compounds, carboxymethyl group-containing phenol compounds, and the like.

Among these, methylol group-containing phenol compounds, methoxymethyl group-containing melamine compounds, methoxymethyl group-containing phenol compounds, methoxymethyl group-containing glycoluril compounds, methoxymethyl group-containing urea compounds, and acetoxymethyl group-containing phenol compound are preferable, methoxymethyl group-containing melamine compounds (e.g., hexamethoxymethylmelamine), methoxymethyl group-containing glycoluril compounds, and methoxymethyl group-containing urea compounds are more preferable, and 1,3-bis(methoxymethyl)urea and 1,3,4,6-tetrakis(methoxymethyl)glycoluril are particularly preferable.

Examples of a commercially available methoxymethyl group-containing melamine compound include CYMEL 300, CYMEL 301, CYMEL 303, CYMEL 305 (manufactured by CYTEC Industries), and the like. Examples of a commercially available methoxymethyl group-containing glycoluril compound include CYMEL 1174 (manufactured by CYTEC Industries) and the like. Examples of a commercially available methoxymethyl group-containing urea compound include MX290 (manufactured by Sanwa Chemical Co., Ltd.) and the like. These crosslinking agents (D) may be used either alone or in combination.

A polymer that includes any of the above crosslinkable functional groups may preferably be used as the crosslinking agent (D). Specifically, a polymer obtained by substituting the hydrogen atom of the acidic group included in the repeating unit (a1) or the like included in the polymer (A1) or the polymer (A2) with any of the above crosslinkable functional groups may be used as the crosslinking agent (D). In this case, the introduction rate (content) of the crosslinkable functional group may be determined depending on the type of the crosslinkable functional group, the type of the polymer, and the like, but is preferably 5 to 60 mol %, more preferably 10 to 50 mol %, and particularly preferably 15 to 40 mol %. If the introduction rate of the crosslinkable functional group is less than 5 mol %, a crosslinking reaction due to the crosslinking agent (D) may not proceed sufficiently (i.e., the amount (degree) of crosslinking may be sufficient), so that the shape (height) of the resist pattern may be deteriorated (decreased), and meandering, swelling, or the like may easily occur. If the introduction rate of the crosslinkable functional group exceeds 60 mol %, the developability of the unexposed area may be deteriorated.

### [1-5] Acid Diffusion Controller (E)

The radiation-sensitive composition according to the embodiment of the invention may further include an acid diffusion controller (hereinafter may be referred to as “acid diffusion controller (E)”). The acid diffusion controller (E) controls a phenomenon in which the acid generated by the acid generator (B) upon exposure to radiation is diffused in the resist film, and suppresses undesired chemical reactions in the unexposed area (i.e., a reaction (deprotection reaction) that causes the acid-dissociable group of the acid-dissociable group-containing polymer to dissociate in the unexposed area).

When the radiation-sensitive composition according to the embodiment of the invention includes the acid diffusion controller (E), the resolution of the resulting resist can be improved while suppressing a change in line width of the resist pattern due to a change in post-exposure delay (PED) from exposure to post-exposure bake (i.e., the radiation-sensitive composition exhibits excellent process stability).

Examples of the acid diffusion controller (E) include nitrogen-containing organic compounds and the like. Examples of the nitrogen-containing organic compounds include a compound shown by the following general formula (E1) (hereinafter may be referred to as “nitrogen-containing compound (E1)”), a compound shown by the following general formula (E2) (hereinafter may be referred to as “nitrogen-containing compound (E2)”), a polyamino compound or polymer that includes three or more nitrogen atoms (hereinafter may be referred to as “nitrogen-containing compound (E3)”), an amide group-containing compound (E4), a urea compound (E5), a nitrogen-containing heterocyclic compound (E6), and the like.

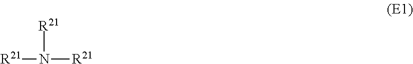

wherein, in the general formula (E1), R²¹ independently represent a hydrogen atom, a substituted or unsubstituted linear, branched, or cyclic alkyl group, a substituted or unsubstituted aryl group, or a substituted or unsubstituted aralkyl group.

Examples of the nitrogen-containing compound (E1) include trialkylamines such as trioctylamine, di(cycloalkyl)amines, tri(cycloalkyl)amines, substituted alkylamines (e.g., trialcohol amine), and aromatic amines such as aniline.

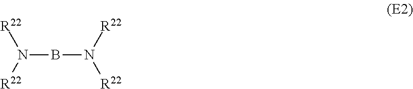

wherein, in the general formula (E2), R²² independently represent a hydrogen atom, a substituted or unsubstituted linear, branched, or cyclic alkyl group, a substituted or unsubstituted aryl group, or a substituted or unsubstituted aralkyl group; and B represents a single bond, an alkylene group having 1 to 6 carbon atoms, an oxygen atom, a carbonyl group, or a carbonyloxy group.

Examples of the nitrogen-containing compound (E2) include N,N,N′,N′-tetrakis(2-hydroxypropyl)ethylenediamine and the like.

Examples of the nitrogen-containing compound (E3) include triazines, polyethyleneimine, polyallylamine, polymer of 2-dimethylaminoethylacrylamide, and the like.

Examples of the amide group-containing compound (E4) include a compound shown by the following general formula (E4) and the like.

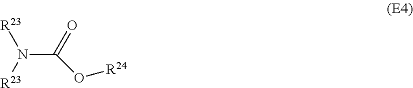

wherein, in the general formula (E4), R²³ independently represent a hydrogen atom, a substituted or unsubstituted linear, branched, or cyclic alkyl group, a substituted or unsubstituted aryl group, or a substituted or unsubstituted aralkyl group, provided that R²³ may bond to each other to form a heterocyclic structure together with the nitrogen atom that is bonded to R²³; and R²⁴ represents a substituted or unsubstituted linear, branched, or cyclic alkyl group having 1 to 10 carbon atoms, a substituted or unsubstituted aryl group, or a substituted or unsubstituted aralkyl group.

Specific examples of the amide group-containing compound (E4) include 2-phenylbenzimidazole-1-carboxylic acid and the like.

Examples of the urea compound (E5) include urea, methylurea, 1,1-dimethylurea, 1,3-dimethylurea, 1,1,3,3-tetramethylurea, 1,3-diphenylurea, tri-n-butylthiourea, and the like.

Examples of the nitrogen-containing heterocyclic compound (E6) include imidazoles such as 2-phenylbenzimidazole, pyridines, piperazines, piperidines such as 3-piperidino-1,2-propanediol, triazines, morpholines, pyrazine, pyrazole, pyridazine, quinoxaline, purine, pyrrolidine, 1,4-diazabicyclo[2.2.2]octane, and the like.

Further examples of the acid diffusion controller (E) include onium salt compounds such as an iodonium salt compound (E7) shown by the following general formula (E7) and a sulfonium salt compound (E8) shown by the following general formula (E8).

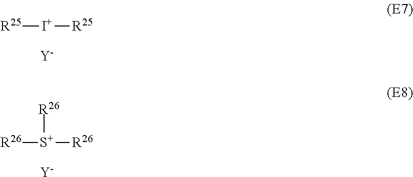

wherein, in the general formulas (E7) and (E8), represents a carbonate anion shown by R—COO⁻, R represents a substituted or unsubstituted linear, branched, or cyclic alkyl group having 1 to 20 carbon atoms, a substituted or unsubstituted aryl group having 1 to 20 carbon atoms, a substituted or unsubstituted linear, branched, or cyclic alkenyl group having 1 to 20 carbon atoms, a substituted or unsubstituted branched or cyclic alkynyl group, or a substituted or unsubstituted branched or cyclic alkoxy group; in the general formula (E7), R²⁵ independently represent a substituted or unsubstituted linear or branched alkyl group having 1 to 10 carbon atoms or a substituted or unsubstituted aryl group having 6 to 18 carbon atoms, provided that R²⁵ may bond to each other to form a cyclic structure together with the iodine atom that is bonded to R²⁵; and in the general formula (E8), R²⁶ independently represent a substituted or unsubstituted linear or branched alkyl group having 1 to 10 carbon atoms or a substituted or unsubstituted aryl group having 6 to 18 carbon atoms, provided that two of R²⁶ may bond to each other to form a cyclic structure together with the sulfur atom that is bonded to R²⁶, and the remainder of R²⁶ may represent a substituted or unsubstituted linear or branched alkyl group having 1 to 10 carbon atoms or a substituted or unsubstituted aryl group having 6 to 18 carbon atoms.

Examples of the onium salt compounds include triphenylsulfonium salicylate, triphenylsulfonium 4-trifluoromethylsalicylate, and the like.

These acid diffusion controllers (E) may be used either alone or in combination.

The acid diffusion controller (E) is preferably used in an amount of 60 parts by mass or less, more preferably 0.001 to 50 parts by mass, and particularly preferably 0.005 to 40 parts by mass, based on 100 parts by mass of the polymer component (A). If the amount of the acid diffusion controller (E) is too large, the sensitivity and the developability of the resulting resist may be deteriorated. If the amount of the acid diffusion controller (E) is too small, the shape or the dimensional accuracy of the resulting resist pattern may be deteriorated depending on the lithographic process conditions.

### [1-6] Additive

The radiation-sensitive composition according to the embodiment of the invention may further include an additive in addition to the above components. Examples of the additive include a surfactant that improves the applicability or striation resistance of the radiation-sensitive composition and the developability of the resulting resist, and the like.

Examples of the surfactant include polyoxyethylene lauryl ether, polyoxyethylene stearyl ether, polyoxyethylene oleyl ether, polyoxyethylene n-octyl phenol ether, polyoxyethylene n-nonyl phenol ether, polyethylene glycol dilaurate, polyethylene glycol distearate, and the like. Examples of a commercially available surfactant include EFTOP EF301, EFTOP EF303, EFTOP EF352 (manufactured by Mitsubishi Materials Electronic Chemicals Co., Ltd.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.), KP341 (manufactured by Shin-Etsu Chemical Co., Ltd.), Polyflow No. 75, Polyflow No. 95 (manufactured by Kyoeisha Chemical Co., Ltd.), and the like. These surfactants may be used either alone or in combination.

The surfactant is preferably used in an amount of 2 parts by mass or less based on 100 parts by mass of the polymer component (A).

### [1-7] Preparation of Radiation-Sensitive Composition

The radiation-sensitive composition according to the embodiment of the invention may be prepared by dissolving a raw material composition prepared by mixing each component in the solvent component (C), and filtering the solution through a filter having a pore size of about 0.2 μmm.

### [2] Method for Forming Negative Type Resist Pattern

The radiation-sensitive composition according to the embodiment of the invention is useful as a chemically-amplified resist. A method for forming a negative type resist pattern using the radiation-sensitive composition according to the embodiment of the invention is described below.

A resist film is formed on a substrate using the radiation-sensitive composition (composition solution) according to the embodiment of the invention. The resist film is exposed by applying radiation to the resist film through holes formed in a mask that is disposed in the optical path. In this case, the acidic group included in the polymer (A1) reacts with the crosslinking agent (D), and is crosslinked due to the sulfonic acid generated by the acid generator (B) upon exposure. The exposed area of the resist film that includes the crosslinked polymer (A1) exhibits low solubility in an alkaline developer. The resist film is then developed using an alkaline developer (i.e., the unexposed area of the resist film is dissolved and removed by the developer) to form a negative type resist pattern. The method for forming a resist pattern is described in detail below.

The composition solution is applied to the substrate (e.g., silicon wafer or aluminum-coated wafer) using an appropriate coating method (e.g., spin coating, cast coating, or roll coating) to form a resist film.

The resist film is optionally pre-baked (PB), and is exposed through a mask that is designed to form a given resist pattern. Radiation used for exposure may be appropriately selected from visible rays, ultraviolet rays, deep ultraviolet rays, X-rays, charged particle rays, and the like. It is preferable to use deep ultraviolet rays such as ArF excimer laser light (wavelength: 193 nm) or KrF excimer laser light (wavelength: 248 nm), and it is particularly preferable to use KrF excimer laser light (wavelength: 248 nm). It is preferable to perform post-exposure bake (PEB) after exposure. PEB ensures a smooth crosslinking reaction in the resist film due to the crosslinking agent (D). The PEB temperature is determined depending on the composition of the radiation-sensitive composition, but is preferably 30 to 200° C., and more preferably 50 to 170° C.

A protective film may be formed on the resist film in order to prevent the effects of basic impurities and the like contained in the environmental atmosphere (see Japanese Patent Application Publication No. 5-188598, for example).

The unexposed area of the resist film is developed to form a given resist pattern. An alkaline aqueous solution prepared by dissolving at least one alkaline compound selected from the group consisting of sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, and 1,5-diazabicyclo-[4.3.0]-5-nonene is preferable as the developer. The concentration of the alkaline aqueous solution is preferably 10 mass % or less. If the concentration of the alkaline aqueous solution exceeds 10 mass %, the exposed area may also be dissolved in the developer.

An organic solvent may be added to the developer, for example. Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methanol, ethanol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene, phenol, acetonylacetone, dimethylformamide, and the like. These organic solvents may be used either alone or in combination.

The organic solvent is preferably used in an amount of 100 parts by volume or less based on 100 parts by volume of the alkaline aqueous solution. If the amount of the organic solvent exceeds 100 parts by volume, the unexposed area may remain undeveloped due to a decrease in developability. An appropriate amount of a surfactant or the like (e.g., the surfactant mentioned above in connection with the radiation-sensitive composition) may also be added to the developer. The resist film is preferably rinsed with water, and dried after development using the developer.

### EXAMPLES

The invention is further described below by way of examples. Note that the invention is not limited to the following examples. The property value measuring methods and the property evaluation methods employed in the examples and comparative examples are described below.

Sensitivity (mJ/cm²)

A dose at which a line-and-space (1L1S) resist pattern (design dimension: 0.15 μm) was formed was determined to be an optimum dose. The optimum dose was evaluated as the sensitivity. The evaluation results are shown in Table 3 or 4 (see “Sensitivity (mJ/cm²)”).

Note that the term “line-and-space (1L1S) pattern” used herein refers to a resist pattern in which a plurality of rectangular protrusions (line areas) formed on a substrate is arranged in parallel, and the width of each protrusion (line area) is equal to the width of the space (space area) between the protrusions.

### Resolution (μm)

The minimum line width (dimension) (μm) of a resist pattern resolved at the optimum dose was evaluated as the resolution. The evaluation results are shown in Table 3 or 4 (see “Resolution (μm)”).

### Storage Stability

A resist pattern was formed using the composition solution that had been stored at 23° C. for 6 months after preparation. A case where the resist pattern had the same resolution and pattern shape as those of a resist pattern formed using the composition solution immediately after preparation, and a change in optimum dose when forming a line-and-space (1L1S) pattern (design dimension: 0.15 μm) was less than ±2% was evaluated as “Acceptable” (indicated by “A” in Table 3 or 4), a case where the resist pattern had the same resolution and pattern shape as those of a resist pattern formed using the composition solution immediately after preparation, and a change in optimum dose when forming a line-and-space (1L1S) pattern (design dimension: 0.15 μm) was 12 to 5% was evaluated as “Fair” (indicated by “B” in Table 3 or 4), and a case where at least one of the resolution and the pattern shape of the resist pattern differed from those of a resist pattern formed using the composition solution immediately after preparation, and a change in optimum dose when forming a line-and-space (1L1S) pattern (design dimension: 0.15 μm) was more than ±5% was evaluated as “Unacceptable” (indicated by “C” in Table 3 or 4).

### Effects of Standing Waves

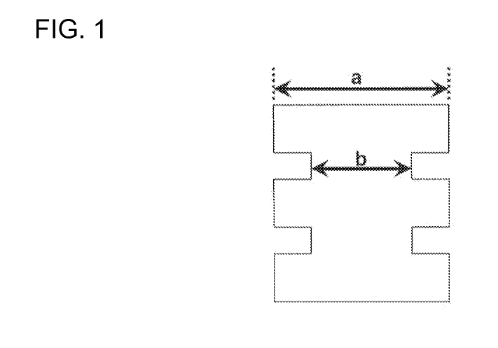

The cross-sectional shape of a line-and-space (1L1S) pattern (design dimension: 0.15 μm) resolved at the optimum dose was observed using an ultra-high resolution field emission scanning electron microscope (“S-4800” manufactured by Hitachi High-Technologies Corporation) to measure the line widths a and b shown in FIG. 1. The line width a is the line width (μm) of an area having the maximum width, and the line width b is the line width (μm) of an area having the minimum width. A case where the ratio “b/a” was 0.8 or more was evaluated as “A”, a case where the ratio “b/a” was 0.6 or more and less than 0.8 was evaluated as “B”, and a case where the ratio “b/a” was less than 0.6, or the resist pattern collapsed or broke, or a line-and-space pattern having a line width of 0.15 μm was not resolved was evaluated as “C”. The evaluation results are shown in Table 3 or 4 (see “Effects of standing waves”). Note that FIG. 1 is a cross-sectional view schematically illustrating the effects of standing waves in a line area of a resist pattern.

### Example 1

100 parts by mass of a polymer (A1-1) (p-hydroxystyrene/styrene copolymer, copolymerization molar ratio=8:2, Mw=4000, dispersity (Mw/Mn)=1.5) (polymer (A1)), 3 parts by mass of an acid generator (B-1) (acid generator (B)), 1 part by mass of an acid generator (B-5) (acid generator (B)), 50 parts by mass of a solvent (C1-1) (solvent (C1)), 700 parts by mass of a solvent (C2-1) (solvent (C2)), 300 parts by mass of a solvent (C2-2) (solvent (C2)), 7 parts by mass of a crosslinking agent (D-1) (crosslinking agent (D)), and 30 parts by mass of an acid diffusion controller (E-1) (acid diffusion controller (E)) were mixed to prepare a homogeneous solution. The solution was filtered through a membrane filter having a pore size of 0.2 μm to obtain a composition solution. The composition solution was spin-coated onto a silicon wafer, and pre-baked (PB) at 90° C. for 60 seconds to form a resist film of Example 1 having a thickness of 0.2 μm.

The resist film was exposed to KrF excimer laser light (wavelength: 248 nm) via a mask pattern using a KrF excimer laser exposure system (“NSR-S203B” manufactured by Nikon Corporation) (numerical aperture: 0.68), and subjected to PEB at 120° C. for 60 seconds. The resist film was subjected to puddle development at 23° C. for 60 seconds using a 2.38 mass % tetramethylammonium hydroxide aqueous solution. The resist film was then rinsed with purified water for 30 seconds, and dried to form a resist pattern of Example 1. The resist pattern thus obtained was evaluated as described above. The evaluation results are shown in Table 3 or 4. Table 1 and 2 show the composition of the composition solution used to form the resist pattern.

TABLE 1

| | Polymer | | | | Solvent | | | | | | | |
|---|---|---|---|---|---|---|---|---|---|---|---|---|
| | component (A) | | Radiation-sensitive | | component (C) | | | | Crosslinking | | Acid diffusion | |
| | Polymer (A1)/(A2) | | acid generator (B) | | Solvent (C1) | | Solvent (C2) | | agent (D) | | controller (E) | |
| | | Amount | | Amount | | Amount | | Amount | | Amount | | Amount |
| | | (parts | | (parts | | (parts | | (parts | | (parts | | (parts |
| | Type | by mass) | Type | by mass) | Type | by mass) | Type | by mass) | Type | by mass) | Type | by mass) |
| Example 1 | A1-1 | 100 | B-1 | 3 | C1-1 | 50 | C2-1 | 700 | D-1 | 7 | E-1 | 30 |
| | | | B-5 | 1 | | | C2-2 | 300 | | | | |
| Example 2 | A1-1 | 100 | B-1 | 3 | C1-1 | 100 | C2-1 | 665 | D-1 | 7 | E-1 | 30 |
| | | | B-5 | 1 | | | C2-2 | 285 | | | | |
| Example 3 | A1-1 | 100 | B-1 | 3 | C1-1 | 315 | C2-1 | 515 | D-1 | 7 | E-1 | 30 |
| | | | B-5 | 1 | | | C2-2 | 220 | | | | |
| Example 4 | A1-1 | 100 | B-1 | 3 | C1-1 | 50 | C2-1 | 700 | D-1 | 7 | E-1 | 30 |
| | | | B-6 | 1 | | | C2-2 | 300 | | | | |
| Example 5 | A1-1 | 100 | B-2 | 3 | C1-2 | 50 | C2-1 | 700 | D-1 | 7 | E-2 | 30 |
| | | | B-5 | 1 | | | C2-2 | 300 | | | | |
| Example 6 | A1-1 | 100 | B-2 | 3 | C1-2 | 50 | C2-1 | 700 | D-1 | 7 | E-1 | 30 |
| | | | B-6 | 1 | | | C2-2 | 300 | | | | |
| Example 7 | A1-1 | 100 | B-3 | 3 | C1-2 | 50 | C2-1 | 700 | D-1 | 7 | E-3 | 30 |
| | | | B-5 | 1 | | | C2-2 | 300 | | | | |
| Example 8 | A1-1 | 100 | B-3 | 3 | C1-2 | 50 | C2-1 | 700 | D-1 | 7 | E-2 | 30 |
| | | | B-6 | 1 | | | C2-2 | 300 | | | | |
| Example 9 | A1-1 | 100 | B-3 | 3 | C1-3 | 50 | C2-1 | 700 | D-1 | 7 | E-3 | 30 |
| | | | B-5 | 1 | | | C2-2 | 300 | | | | |
| Example 10 | A1-1 | 100 | B-3 | 3 | C1-3 | 50 | C2-1 | 700 | D-1 | 7 | E-2 | 30 |
| | | | B-6 | 1 | | | C2-2 | 300 | | | | |
| Example 11 | A1-1 | 100 | B-1 | 3 | C1-4 | 50 | C2-1 | 700 | D-1 | 7 | E-3 | 30 |
| | | | B-5 | 1 | | | C2-2 | 300 | | | | |
| Example 12 | A1-1 | 100 | B-1 | 3 | C1-4 | 50 | C2-1 | 700 | D-1 | 7 | E-2 | 30 |
| | | | B-6 | 1 | | | C2-2 | 300 | | | | |
| Example 13 | A1-1 | 100 | B-1 | 3 | C1-5 | 50 | C2-1 | 700 | D-1 | 7 | E-3 | 30 |
| | | | B-5 | 1 | | | C2-2 | 300 | | | | |
| Example 14 | A1-2 | 100 | B-1 | 3 | C1-1 | 50 | C2-1 | 700 | D-1 | 7 | E-1 | 30 |
| | | | B-5 | 1 | | | C2-2 | 300 | | | | |
| Example 15 | A1-2 | 100 | B-1 | 3 | C1-1 | 50 | C2-1 | 700 | D-1 | 7 | E-2 | 30 |
| | | | B-6 | 1 | | | C2-2 | 300 | | | | |
| Example 16 | A1-2 | 100 | B-2 | 3 | C1-2 | 50 | C2-1 | 700 | D-1 | 7 | E-3 | 30 |
| | | | B-5 | 1 | | | C2-2 | 300 | | | | |
| Example 17 | A1-2 | 100 | B-2 | 3 | C1-2 | 50 | C2-1 | 700 | D-1 | 7 | E-1 | 30 |
| | | | B-6 | 1 | | | C2-2 | 300 | | | | |
| Example 18 | A1-2 | 100 | B-3 | 3 | C1-3 | 50 | C2-1 | 700 | D-1 | 7 | E-1 | 30 |
| | | | B-5 | 1 | | | C2-2 | 300 | | | | |
| Example 19 | A1-2 | 100 | B-3 | 3 | C1-3 | 50 | C2-1 | 700 | D-1 | 7 | E-2 | 30 |
| | | | B-6 | 1 | | | C2-2 | 300 | | | | |
| Example 20 | A1-2 | 100 | B-4 | 3 | C1-2 | 50 | C2-1 | 700 | D-1 | 7 | E-2 | 30 |
| | | | B-5 | 1 | | | C2-2 | 300 | | | | |

TABLE 2

| | Polymer | | | | Solvent | | | | | | | |
|---|---|---|---|---|---|---|---|---|---|---|---|---|
| | component (A) | | Radiation-sensitive | | component (C) | | | | Crosslinking | | Acid diffusion | |
| | Polymer (A1)/(A2) | | acid generator (B) | | Solvent (C1) | | Solvent (C2) | | agent (D) | | controller (E) | |
| | | Amount | | Amount | | Amount | | Amount | | Amount | | Amount |
| | | (parts | | (parts | | (parts | | (parts | | (parts | | (parts |
| | Type | by mass) | Type | by mass) | Type | by mass) | Type | by mass) | Type | by mass) | Type | by mass) |
| Example 21 | A1-1 | 50 | B-3 | 3 | C1-3 | 50 | C2-1 | 700 | D-1 | 7 | E-4 | 30 |
| | A1-2 | 50 | B-5 | 1 | | | C2-2 | 300 | | | | |
| Example 22 | A1-1 | 50 | B-3 | 3 | C1-3 | 50 | C2-1 | 700 | D-1 | 7 | E-2 | 30 |
| | A1-2 | 50 | B-6 | 1 | | | C2-2 | 300 | | | | |
| Example 23 | A1-1 | 50 | B-1 | 3 | C1-3 | 50 | C2-1 | 700 | D-1 | 7 | E-2 | 30 |
| | A1-2 | 50 | B-2 | 1 | | | C2-2 | 300 | | | | |
| Example 24 | A2-1 | 50 | B-2 | 2 | C1-2 | 50 | C2-1 | 700 | — | — | E-3 | 15 |
| | A2-2 | 50 | B-7 | 10 | | | C2-2 | 300 | | | | |
| Example 25 | A2-1 | 50 | B-2 | 2 | C1-3 | 50 | C2-1 | 700 | — | — | E-3 | 15 |
| | A2-2 | 50 | B-7 | 10 | | | C2-2 | 300 | | | | |
| Comparative | A1-1 | 100 | B-1 | 3 | — | — | C2-1 | 735 | D-1 | 7 | E-3 | 30 |
| Example 1 | | | B-2 | 1 | | | C2-2 | 315 | | | | |
| Comparative | A1-1 | 100 | B-1 | 3 | — | — | C2-1 | 735 | D-1 | 7 | E-1 | 30 |
| Example 2 | | | B-5 | 1 | | | C2-2 | 315 | | | | |
| Comparative | A1-1 | 100 | B-3 | 3 | — | — | C2-1 | 735 | D-1 | 7 | E-3 | 30 |
| Example 3 | | | B-5 | 1 | | | C2-2 | 315 | | | | |
| Comparative | A1-1 | 50 | B-3 | 3 | — | — | C2-1 | 735 | D-1 | 7 | E-4 | 30 |
| Example 4 | A1-2 | 50 | B-5 | 1 | | | C2-2 | 315 | | | | |
| Comparative | A2-1 | 50 | B-2 | 2 | — | — | C2-1 | 735 | D-1 | 7 | E-3 | 15 |
| Example 5 | A2-2 | 50 | B-7 | 10 | | | C2-2 | 315 | | | | |
| Comparative | A2-1 | 50 | B-2 | 2 | — | — | C2-1 | 735 | — | — | E-3 | 15 |
| Example 6 | A2-2 | 50 | B-7 | 10 | | | C2-2 | 315 | | | | |
| Comparative | A1-1 | 100 | B-1 | 3 | C1-6 | 50 | C2-1 | 700 | — | — | E-3 | 15 |
| Example 7 | | | B-5 | 1 | | | C2-2 | 300 | | | | |
| Comparative | A1-1 | 100 | B-1 | 3 | C1-7 | 50 | C2-1 | 700 | — | — | E-3 | 15 |
| Example 8 | | | B-5 | 1 | | | C2-2 | 300 | | | | |
| Comparative | A1-1 | 100 | B-1 | 3 | C1-6 | 50 | C2-1 | 700 | D-1 | 7 | E-3 | 30 |
| Example 9 | | | B-5 | 1 | | | C2-2 | 300 | | | | |
| Comparative | A1-1 | 100 | B-1 | 3 | C1-7 | 50 | C2-1 | 700 | D-1 | 7 | E-3 | 30 |
| Example 10 | | | B-5 | 1 | | | C2-2 | 300 | | | | |

TABLE 3

| | | | | | Effects |
|---|---|---|---|---|---|
| | Sensitivity | Resolution | Storage | | of standing |
| | (mJ/cm²) | (μm) | stability | b/a | waves |
| Example 1 | 4.0 × 10² | 0.15 | A | 0.9 | A |
| Example 2 | 4.1 × 10² | 0.15 | A | 0.9 | A |
| Example 3 | 4.3 × 10² | 0.15 | A | 0.9 | A |
| Example 4 | 4.2 × 10² | 0.15 | A | 0.9 | A |
| Example 5 | 3.8 × 10² | 0.13 | A | 0.9 | A |
| Example 6 | 4.4 × 10² | 0.14 | A | 0.9 | A |
| Example 7 | 3.5 × 10² | 0.13 | A | 0.9 | A |
| Example 8 | 3.2 × 10² | 0.13 | A | 0.9 | A |
| Example 9 | 3.7 × 10² | 0.14 | A | 0.9 | A |
| Example 10 | 3.8 × 10² | 0.13 | A | 0.9 | A |
| Example 11 | 3.0 × 10² | 0.15 | A | 0.7 | B |
| Example 12 | 3.1 × 10² | 0.15 | A | 0.7 | B |
| Example 13 | 3.4 × 10² | 0.15 | A | 0.7 | B |
| Example 14 | 3.2 × 10² | 0.15 | A | 0.9 | A |
| Example 15 | 3.3 × 10² | 0.15 | A | 0.9 | A |
| Example 16 | 3.1 × 10² | 0.14 | A | 0.9 | A |
| Example 17 | 4.4 × 10² | 0.14 | A | 0.9 | A |
| Example 18 | 4.3 × 10² | 0.14 | A | 0.9 | A |
| Example 19 | 3.5 × 10² | 0.13 | A | 0.9 | A |
| Example 20 | 3.8 × 10² | 0.13 | A | 0.9 | A |

TABLE 4

| | | | | | Effects |
|---|---|---|---|---|---|
| | Sensitivity | Resolution | Storage | | of standing |
| | (mJ/cm²) | (μm) | stability | b/a | waves |
| Example 21 | 4.0 × 10² | 0.14 | A | 0.9 | A |
| Example 22 | 3.3 × 10² | 0.14 | A | 0.9 | A |
| Example 23 | 3.4 × 10² | 0.13 | A | 0.9 | A |
| Example 24 | 4.4 × 10² | 0.13 | A | 0.9 | A |
| Example 25 | 3.8 × 10² | 0.13 | A | 0.9 | A |
| Comparative | 3.5 × 10² | 0.18 | A | — | C |
| Example 1 | | | | | |
| Comparative | 3.9 × 10² | 0.18 | A | — | C |
| Example 2 | | | | | |
| Comparative | 3.5 × 10² | 0.18 | A | — | C |
| Example 3 | | | | | |
| Comparative | 3.9 × 10² | 0.18 | A | — | C |
| Example 4 | | | | | |
| Comparative | 3.9 × 10² | 0.18 | A | — | C |
| Example 5 | | | | | |
| Comparative | 4.5 × 10² | 0.16 | A | 0.5 | C |
| Example 6 | | | | | |
| Comparative | 4.0 × 10² | 0.15 | A | 0.5 | C |
| Example 7 | | | | | |
| Comparative | 4.3 × 10² | 0.15 | A | 0.5 | C |
| Example 8 | | | | | |
| Comparative | 3.0 × 10² | 0.15 | A | 0.5 | C |
| Example 9 | | | | | |
| Comparative | 3.4 × 10² | 0.15 | A | 0.5 | C |
| Example 10 | | | | | |

### Examples 2 to 25 and Comparative Examples 1 to 10

Composition solutions of Examples 2 to 25 and Comparative Examples 1 to 10 were prepared in the same manner as in Example 1, except that the composition was changed as shown in Table 1 or 2. A resist pattern was formed in the same manner as in Example 1, except that the resulting composition solution was used. The resist pattern thus obtained was evaluated as described above. The evaluation results are shown in Table 3 or 4.

The following compounds were used in the examples and comparative examples (see Tables 1 and 2).

### Polymer (A1)

A1-1: p-hydroxystyrene/styrene copolymer (copolymerization molar ratio=8:2, Mw=4000, dispersity=1.5)
A1-2: p-hydroxystyrene/styrene copolymer (copolymerization molar ratio=7:3, Mw=4000, dispersity=1.5)

### Polymer (A2)

A2-1: p-hydroxystyrene/styrene/p-t-butoxystyrene copolymer (copolymerization molar ratio=77:5:18, Mw=16,000, dispersity=1.7)
A2-2: p-hydroxystyrene/styrene/p-t-butoxystyrene copolymer (copolymerization molar ratio=67:5:28, Mw=16,000, dispersity=1.7)

### Acid Generator (B)

B-1: triphenylsulfonium p-toluenesulfonate
B-2: triphenylsulfonium 2,4-difluorobenzenesulfonate
B-3: 2,4,6-trimethylphenyldiphenylsulfonium 2,4-difluorobenzenesulfonate
B-4: triphenylsulfonium 10-camphorsulfonate
B-5: triphenylsulfonium trifluoromethanesulfonate
B-6: diphenyl-4-hydroxyphenylsulfonium trifluoromethanesulfonate
B-7: N-(trifluoromethanesulfonyloxy)bicyclo[2.2.1]hept-5-ene-2,3-dicarboxyimide

### Solvent (C1)

C1-1: diethylene glycol diethyl ether (boiling point: 189° C.)
C1-2: diethylene glycol monoethyl ether acetate (boiling point: 217° C.)
C1-3: dipropylene glycol monomethyl ether acetate (boiling point: 213° C.)
C1-4: δ-valerolactone (boiling point: 230° C.)
C1-5: 4-ethyl-1,3-dioxan-2-one (boiling point: 251° C.)
C1-6: γ-butyrolactone (boiling point: 204° C.)
C1-7: propylene carbonate (boiling point: 240° C.)

### Solvent (C2)

C2-1: ethyl lactate (boiling point: 155° C.)
C2-2: propylene glycol monomethyl ether acetate (boiling point: 146° C.)

### Crosslinking Agent (D)

D-1: 1,3,4,6-tetrakis(methoxymethyl)glycoluril

### Acid Diffusion Controller (E)

E-1: trioctylamine
E-2: 3-piperidino-1,2-propanediol
E-3: 2-phenylbenzimidazole
E-4: triphenylsulfonium salicylate

As shown in Tables 3 and 4, the resist films of Examples 1 to 25 exhibited excellent sensitivity and resolution, and the resist patterns of Examples 1 to 25 were less affected by standing waves. In contrast, the resist patterns of Comparative Examples 1 to 10 were affected by standing waves due to the absence of the solvent (C1-a), (C1-b), or (C1-c), and irregularity due to standing waves were observed on the sidewall of each resist pattern. A defect (e.g., breakage or collapse) was also observed in the resist patterns of Comparative Examples 1 to 10.

The radiation-sensitive composition according to the embodiment of the invention may be useful as a resist material suitable for microfabrication that utilizes various types of radiation (e.g., ultraviolet rays, deep ultraviolet rays, X-rays, and charged particle rays).

Obviously, numerous modifications and variations of the present invention are possible in light of the above teachings. It is therefore to be understood that within the scope of the appended claims, the invention may be practiced otherwise than as specifically described herein.

1. A radiation-sensitive composition comprising:
a polymer component including a first polymer that includes an acidic group, a group in which an acidic group is protected by an acid-dissociable group, or a both thereof;
a radiation-sensitive acid generator; and
a solvent component including a first solvent which is a solvent shown by a general formula (C1-a), a solvent shown by a general formula (C1-b), a solvent shown by a general formula (C1-c), or a mixture thereof, 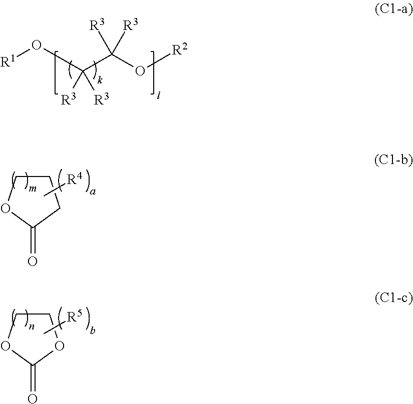
wherein,
in the general formula (C1-a),
each of R¹ and R² independently represents a hydrogen atom, a linear or branched alkyl group having 1 to 10 carbon atoms, an aryl group having 6 to 15 carbon atoms, an aralkyl group having 7 to 15 carbon atoms, a halogen atom, a group shown by a general formula (c1), or a group shown by a general formula (c2);
each R³ independently represents a hydrogen atom, a linear or branched alkyl group having 1 to 5 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2);
k is an integer from 1 to 10; and
l is an integer from 2 to 5,
in the general formula (C1-b),
R⁴ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2);
m is an integer from 2 to 4; and
a is an integer from 0 to 12, wherein in case a plurality of R⁴s are present, each of the plurality of R⁴s is identical or different to each other,
in the general formula (C1-c),
R⁵ represents a linear or branched alkyl group having 1 to 10 carbon atoms, an alkoxy group having 1 to 5 carbon atoms, an aryl group having 6 to 15 carbon atoms, an aralkyl group having 7 to 15 carbon atoms, a halogen atom, a hydroxyl group, the group shown by the general formula (c1), or the group shown by the general formula (c2);
n is an integer from 2 to 4; and
b is an integer from 0 to 10, wherein in case a plurality of R⁵s are present, each of the plurality of R⁵s is identical or different to each other, 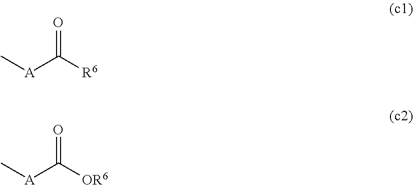
wherein, in the general formulas (c1) and (c2),
each A independently represents a single bond or a divalent hydrocarbon group having 1 to 5 carbon atoms; and
each R⁶ independently represents a hydrogen atom or a monovalent hydrocarbon group having 1 to 5 carbon atoms.

2. The radiation-sensitive composition according to claim 1, wherein a content of the first solvent in the solvent component is 0.01 to 30 mass % of a total amount of the solvent component.

3. The radiation-sensitive composition according to claim 1, wherein the first polymer is a polymer which includes a repeating unit shown by a general formula (a1), 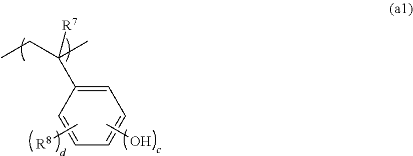
wherein, in the general formula (a1),
R⁷ represents a hydrogen atom, a methyl group, or a trifluoromethyl group;
R⁸ represents a linear or branched alkyl group having 1 to 12 carbon atoms or a linear or branched alkoxy group having 1 to 12 carbon atoms;
c is an integer from 1 to 3; and
d is an integer from 0 to 4, wherein in case a plurality of R⁸s are present, each of the plurality of R⁸s is identical or different to each other.

4. The radiation-sensitive composition according to claim 3, wherein the repeating unit is a repeating unit derived from hydroxystyrene.

5. The radiation-sensitive composition according to claim 1, wherein the polymer component includes a second polymer that includes a group in which an acidic group is protected by an acid-dissociable group.

6. The radiation-sensitive composition according to claim 3, wherein a content of the first polymer in the polymer component is 50 to 100 mass % of a total amount of the polymer component, the radiation-sensitive composition further comprising a crosslinking agent, and being capable of forming a negative type resist pattern.

7. The radiation-sensitive composition according to claim 3, wherein the polymer component includes a second polymer that includes a group in which an acidic group is protected by an acid-dissociable group.
